(19) United States
(12) Patent Application Publication
(10) Pub. No.: US 2017/0294217 A1
(43) Pub. Date: Oct. 12, 2017

(54) DECODING METHOD, MEMORY STORAGE DEVICE AND MEMORY CONTROL CIRCUIT UNIT

(71) Applicant: PHISON ELECTRONICS CORP., Miaoli (TW)

(72) Inventors: Yu-Hsiang Lin, Yunlin County (TW); Shao-Wei Yen, Kaohsiung City (TW); Cheng-Che Yang, New Taipei City (TW); Kuo-Hsin Lai, Hsinchu County (TW)

(21) Appl. No.: 15/170,931

(22) Filed: Jun. 1, 2016

(30) Foreign Application Priority Data
Apr. 8, 2016 (TW) 105111130

(51) Int. Cl. G11C 7/00; G11C 29/52; G06F 11/10

(52) U.S. Cl. CPC G11C 7/00; G06F 11/1068; G11C 29/52

(57) ABSTRACT

A decoding method, a memory storage device and a memory control circuit unit are provided. The method includes: reading data from a plurality of first memory cells of a rewritable non-volatile memory module; estimating an error bit occurrence rate of the data before performing a first decoding process on the data; and performing the first decoding process on the data by using a first decoding parameter according to the estimated error bit occurrence rate, wherein the first decoding parameter corresponds to a strict level for locating an error bit in the first decoding process. As a result, a decoding efficiency of the memory storage device can be improved.

### CROSS-REFERENCE TO RELATED APPLICATION

This application claims the priority benefit of Taiwan application serial no. 105111130, filed on Apr. 8, 2016. The entirety of the above-mentioned patent application is hereby incorporated by reference herein and made a part of this specification.

### BACKGROUND

### Technical Field

The disclosure relates to a decoding technology, and more particularly, to a decoding method, a memory storage device and a memory control circuit unit.

### Description of Related Art

The markets of digital cameras, cellular phones, and MP3 players have expanded rapidly in recent years, resulting in escalated demand for storage media by consumers. The characteristics of data non-volatility, low power consumption, and compact size make a rewritable non-volatile memory module (e.g., a flash memory) ideal to be built in the portable multi-media devices as cited above.

In general, a memory device is built in with one or more decoding mechanisms, which are configured to correct possible errors included in data read from the memory device. For example, the decoding mechanisms may include decoding algorithms such as a Bit-Flipping algorithm, a Min-Sum algorithm, a Sum-Product and the like. When the memory device left the factory, the decoding algorithm built in the memory device is configured to use optimal operating parameters. However, variation will occur on a channel status of the memory device with increases in usage time and/or usage frequency of the memory device. If the variation of the channel status of the memory device is overly severe, the memory device often shows a poor decoding efficiency even if the optimal operating parameters is already in use.

Nothing herein should be construed as an admission of knowledge in the prior art of any portion of the present disclosure. Furthermore, citation or identification of any document in this application is not an admission that such document is available as prior art to the present disclosure, or that any reference forms a part of the common general knowledge in the art.

### SUMMARY

Accordingly, the disclosure is directed to a decoding method, a memory storage device and a memory control circuit unit, which are capable of improving a decoding efficiency of the memory storage device.

An exemplary embodiment of the disclosure provides a decoding method for a rewritable non-volatile memory module including a plurality of memory cells, and the decoding method includes: reading data from a plurality of first memory cells among memory cells; estimating an error bit occurrence rate of the data before performing a first decoding process on the data; and performing the first decoding process on the data by using a first decoding parameter according to the estimated error bit occurrence rate, wherein the first decoding parameter corresponds to a strict level for locating an error bit in the first decoding process.

Another exemplary embodiment of the disclosure provides a memory storage device, which includes a connection interface unit, a rewritable non-volatile memory module and a memory control circuit unit. The connection interface unit is configured to couple to a host system. The rewritable non-volatile memory module includes a plurality of memory cells. The memory control circuit unit is coupled to the connection interface unit and the rewritable non-volatile memory module. The memory control circuit unit is configured to send a read command sequence which instructs reading data from a plurality of first memory cells among the memory cells. The memory control circuit unit is further configured to estimate an error bit occurrence rate of the data before performing a first decoding process on the data. The memory control circuit unit is further configured to perform the first decoding process on the data by using a first decoding parameter according to the estimated error bit occurrence rate, wherein the first decoding parameter corresponds to a strict level for locating an error bit in the first decoding process.

Another exemplary embodiment of the disclosure provides a memory control circuit unit, which is configured to control a rewritable non-volatile memory module. The rewritable non-volatile memory module includes a plurality of memory cells, and the memory control circuit unit includes a host interface, a memory interface, an error checking and correcting circuit and a memory management circuit. The host interface is configured to couple to a host system. The memory interface is configured to couple to a rewritable non-volatile memory module. The memory management circuit is coupled to the host interface, the memory interface and the error checking and correcting circuit. The memory management circuit is configured to send a read command sequence which instructs reading data from a plurality of first memory cells among the memory cells. The memory management circuit is further configured to estimate an error bit occurrence rate of the data before performing a first decoding process on the data. The error checking and correcting circuit is further configured to perform the first decoding process on the data by using a first decoding parameter according to the estimated error bit occurrence rate, wherein the first decoding parameter corresponds to a strict level for locating an error bit in the first decoding process.

Based on the above, according to the error bit occurrence rate of the data to be decoded, the error checking and correcting circuit may flexibly perform the corresponding decoding process based on one specific decoding parameter, where the specific decoding parameter corresponds to a strict level for locating the error bit in the corresponding decoding process. As a result, a balance between improving the decoding succeed rate of each decoding process and improving the overall decoding speed may be accomplished, so as to improve the decoding efficiency of the memory storage device.

To make the above features and advantages of the disclosure more comprehensible, several embodiments accompanied with drawings are described in detail as follows.

It should be understood, however, that this Summary may not contain all of the aspects and embodiments of the present disclosure, is not meant to be limiting or restrictive in any manner, and that the disclosure as disclosed herein is and will be understood by those of ordinary skill in the art to encompass obvious improvements and modifications thereto.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating a host system, a memory storage device and an I/O (input/output) device according to an exemplary embodiment of the disclosure.

FIG. 2 is a schematic diagram illustrating a host system, a memory storage device and an I/O device according to another exemplary embodiment of the disclosure.

FIG. 3 is a schematic diagram illustrating a host system and a memory storage device according to another exemplary embodiment of the disclosure.

FIG. 4 is a schematic block diagram illustrating a memory storage device according to an exemplary embodiment of the disclosure.

FIG. 5 is a schematic block diagram illustrating a memory control circuit unit according to an exemplary embodiment of the disclosure.

FIG. 6 is a schematic diagram illustrating a parity check matrix according to an exemplary embodiment of the disclosure.

FIG. 7 is a schematic diagram illustrating threshold voltage distributions of the memory cells according to an exemplary embodiment of the disclosure.

FIG. 8 is a schematic diagram illustrating a parity check process according to an exemplary embodiment of the disclosure.

FIG. 9 is a flowchart illustrating a decoding method according to an exemplary embodiment of the disclosure.

FIG. 10 is a flowchart illustrating a decoding method according to another exemplary embodiment of the disclosure.

FIG. 11 is a flowchart illustrating a decoding method according to another exemplary embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Embodiments of the present disclosure may comprise any one or more of the novel features described herein, including in the Detailed Description, and/or shown in the drawings. As used herein, “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

It is to be noted that the term “a” or “an” entity refers to one or more of that entity. As such, the terms “a” (or “an”). “one or more” and “at least one” can be used interchangeably herein.

Generally, the memory storage device (also known as a memory storage system) includes a rewritable non-volatile memory module and a controller (also known as a control circuit). The memory storage device is usually configured together with a host system so that the host system may write data into the memory storage device or read data from the memory storage device.

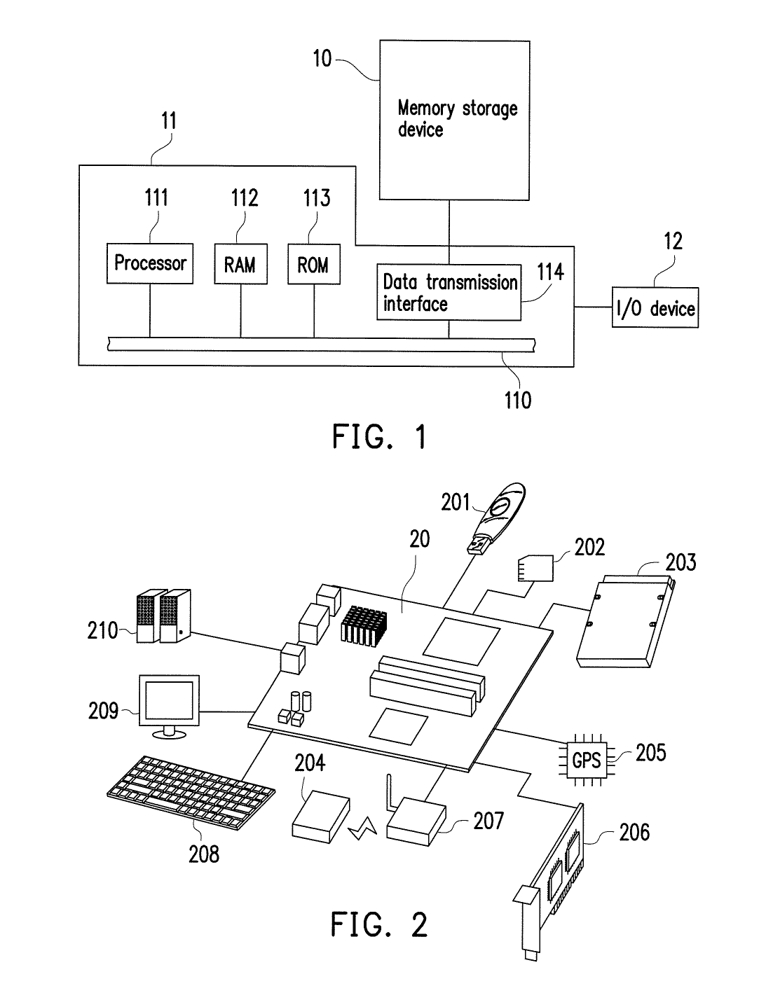

FIG. 1 is a schematic diagram illustrating a host system, a memory storage device and an I/O (input/output) device according to an exemplary embodiment of the disclosure. FIG. 2 is a schematic diagram illustrating a host system, a memory storage device and an I/O device according to another exemplary embodiment of the disclosure.

Referring to FIG. 1 and FIG. 2, a host system 11 generally includes a processor 111, a RAM (random access memory) 112, a ROM (read only memory) 113 and a data transmission interface 114. The processor 111, the RAM 112, the ROM 113 and the data transmission interface 114 are coupled to a system bus 110.

In the present exemplary embodiment, the host system 11 is coupled to a memory storage device 10 through the data transmission interface 114. For example, the host system 11 can store data into the memory storage device 10 or read data from the memory storage device 10 through the data transmission interface 114. Further, the host system 11 is coupled to an I/O device 12 through the system bus 110. For example, the host system 11 can transmit output signals to the I/O device 12 or receive input signals from I/O device 12 through the system bus 110.

In the present exemplary embodiment, the processor 111, the RAM 112, the ROM 113 and the data transmission interface 114 may be disposed on a main board 20 of the host system 11. The number of the data transmission interface 114 may be one or more. Through the data transmission interface 114, the main board 20 may be coupled to the memory storage device 10 in a wired manner or a wireless manner. The memory storage device 10 may be, for example, a flash drive 201, a memory card 202, a SSD (Solid State Drive) 203 or a wireless memory storage device 204. The wireless memory storage device 204 may be, for example, a memory storage device based on various wireless communication technologies, such as a NFC (Near Field Communication) memory storage device, a WiFi (Wireless Fidelity) memory storage device, a Bluetooth memory storage device, a Bluetooth low energy memory storage device (e.g., iBeacon). Further, the main board 20 may also be coupled to various I/O devices including a GPS (Global Positioning System) module 205, a network interface card 206, a wireless transmission device 207, a keyboard 208, a monitor 209 and a speaker 210 through the system bus 110. For example, in an exemplary embodiment, the main board 20 may access the wireless memory storage device 204 through the wireless transmission device 207.

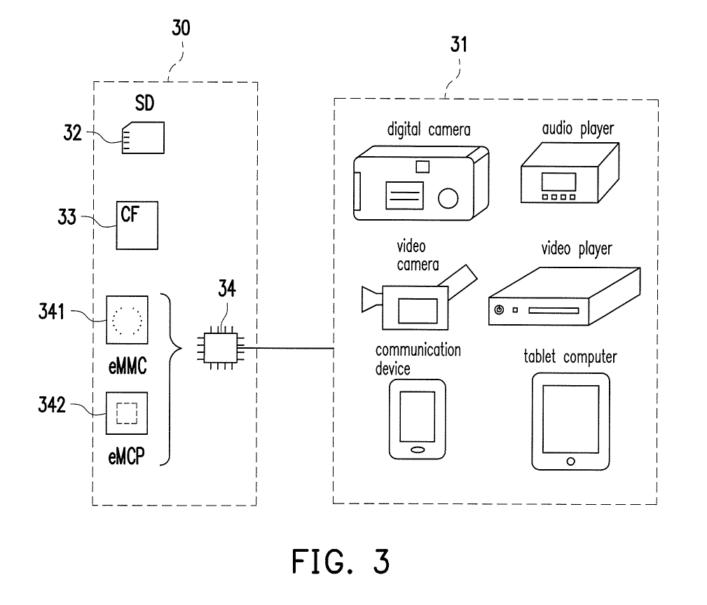

In an exemplary embodiment, aforementioned host system may be any system capable of substantially cooperating with the memory storage device for storing data. The host system is illustrated as a computer system in foregoing exemplary embodiment; nonetheless, FIG. 3 is a schematic diagram illustrating a host system and a memory storage device according to another exemplary embodiment of the disclosure. Referring to FIG. 3, a host system 31 may also be a system including a digital camera, a video camera, a communication device, an audio player, a video player or a tablet computer, whereas a memory storage device 30 may be various non-volatile memory devices used by the host system 31, such as a SD (Secure Digital) card 32, a CF (Compact Flash) card 33 or an embedded storage device 34. The embedded storage device 34 includes various embedded storage devices capable of directly coupling a memory module onto a substrate of the host system 31, such as an eMMC (embedded MMC) 341 and/or an eMCP (embedded Multi Chip Package) storage device 342.

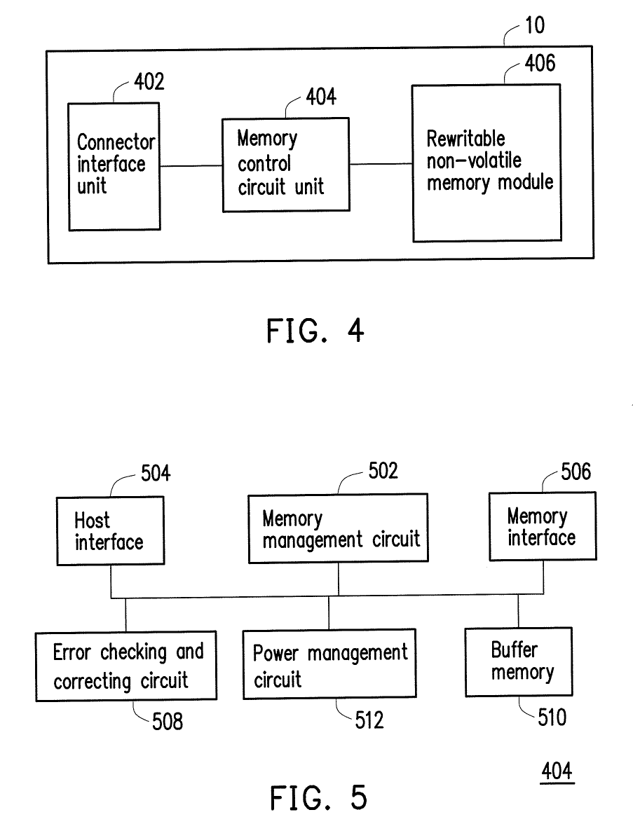

FIG. 4 is a schematic block diagram illustrating a memory storage device according to an exemplary embodiment of the disclosure.

Referring to FIG. 4, the memory storage device 10 includes a connection interface unit 402, a memory control circuit unit 404 and a rewritable non-volatile memory module 406.

In the present exemplary embodiment, the connection interface unit 402 is compatible with a SATA (Serial Advanced Technology Attachment) standard. Nevertheless, it should be understood that the disclosure is not limited thereto. The connection interface unit 402 may also be compatible to a PATA (Parallel Advanced Technology Attachment) standard, an IEEE (Institute of Electrical and Electronic Engineers) 1394 standard, a PCI Express (Peripheral Component Interconnect Express) interface standard, a USB (Universal Serial Bus) standard, a SD interface standard, a UHS-I (Ultra High Speed-I) interface standard, a UHS-II (Ultra High Speed-II) interface standard, a MS (Memory Stick) interface standard, a Multi-Chip Package interface standard, a MMC (Multi Media Card) interface standard, an eMMC interface standard, a UFS (Universal Flash Storage) interface standard, an eMCP interface standard, a CF interface standard, an IDE (Integrated Device Electronics) interface standard or other suitable standards. The connection interface unit 402 and the memory control circuit unit 404 may be packaged into one chip, or the connection interface unit 402 is distributed outside of a chip containing the memory control circuit unit 404.

The memory control circuit unit 404 is configured to execute a plurality of logic gates or control commands which are implemented in a hardware form or in a firmware form and perform operations of writing, reading or erasing data in the rewritable non-volatile memory storage module 406 according to the commands of the host system 11.

The rewritable non-volatile memory module 406 is coupled to the memory control circuit unit 404 and configured to store data written from the host system 11. The rewritable non-volatile memory module 406 may be a SLC (Single Level Cell) NAND flash memory module (i.e., a flash memory module capable of storing one bit in one memory cell), a MLC (Multi Level Cell) NAND flash memory module (i.e., a flash memory module capable of storing two bits in one memory cell), a TLC (Triple Level Cell) NAND flash memory module (i.e., a flash memory module capable of storing three bits in one memory cell), other flash memory modules or any memory module having the same features.

In the present exemplary embodiment, the memory cells of the rewritable non-volatile memory module 406 constitute a plurality of physical programming units, and the physical programming units constitute a plurality of physical erasing units. Specifically, the memory cells on the same word line constitute one or more of the physical programming units. If each of the memory cells can store more than two bits, the physical programming units on the same word line can be at least classified into a lower physical programming unit and an upper physical programming unit. For example, a LSB (Least Significant Bit) of one memory cell belongs to the lower physical programming unit, and a MSB (most significant bit) of one memory cell belongs to the upper physical programming unit. Generally, in the MLC NAND flash memory, a writing speed of the lower physical programming unit is higher than a writing speed of the upper physical programming unit, and/or a reliability of the lower physical programming unit is higher than a reliability of the upper physical programming unit.

In the present exemplary embodiment, the physical programming unit is a minimum unit for programming. That is, the physical programming unit is the minimum unit for writing data. For example, the physical programming unit is a physical page or a physical sector. When the physical programming unit is the physical page, the physical programming unit usually include a data bit area and a redundancy bit area. The data bit area includes multiple physical sectors configured to store user data, and the redundant bit area is configured to store system data (e.g., an error correcting code). In the present exemplary embodiment, the data bit area contains 32 physical sectors, and a size of each physical sector is 512 bytes (B). However, in other exemplary embodiments, the data bit area may also include 8, 16 physical sectors or different number (more or less) of the physical sectors, and the size of each physical sector may also be greater or smaller. On the other hand, the physical erasing unit is the minimal unit for erasing. Namely, each physical erasing unit contains the least number of memory cells to be erased together. For instance, the physical erasing unit is a physical block.

In the present exemplary embodiment, one or more bits in the rewritable non-volatile memory module 406 are stored by changing a voltage (hereinafter, also known as a threshold voltage) of each of the memory cells. More specifically, in each of the memory cells, a charge trapping layer is provided between a control gate and a channel. Amount of electrons in the charge trapping layer may be changed by applying a write voltage to the control gate thereby changing the threshold voltage of the memory cell. This process of changing the threshold voltage is also known as “writing data into the memory cell” or “programming the memory cell”. With changes in the threshold voltage, each of the memory cells in the rewritable non-volatile memory module 406 has a plurality of storage states. The storage state to which the memory cell belongs may be determined by applying a read voltage, so as to obtain the one or more bits stored in the memory cell.

FIG. 5 is a schematic block diagram illustrating a memory control circuit unit according to an exemplary embodiment of the disclosure.

Referring to FIG. 5, the memory control circuit unit 404 includes a memory management circuit 502, a host interface 504, a memory interface 506 and an error checking and correcting circuit 508.

The memory management circuit 502 is configured to control overall operations of the memory control circuit unit 404. Specifically, the memory management circuit 502 has a plurality of control commands. During operations of the memory storage device 10, the control commands are executed to perform various operations such as writing, reading and erasing data. Hereinafter, description for operations of the memory management circuit 502 is equivalent to description for operations of the memory control circuit unit 404.

In the present exemplary embodiment, the control commands of the memory management circuit 502 are implemented in form of firmware. For instance, the memory management circuit 502 has a microprocessor unit (not illustrated) and a ROM (not illustrated), and the control commands are burned into the ROM. When the memory storage device 10 operates, the control commands are executed by the microprocessor to perform operations of writing, reading or erasing data.

In another exemplary embodiment, the control commands of the memory management circuit 502 may also be stored as program codes in a specific area (for example, the system area in a memory exclusively used for storing system data) of the rewritable non-volatile memory module 406. In addition, the memory management circuit 502 has a microprocessor unit (not illustrated), the read only memory (not illustrated) and a random access memory (not illustrated). Particularly, the ROM has a boot code, which is executed by the microprocessor unit to load the control commands stored in the rewritable non-volatile memory module 406 to the RAM of the memory management circuit 502 when the memory control circuit unit 404 is enabled. Later, the control commands are executed by the microprocessor unit to perform operations of writing, reading or erasing data.

Further, in another exemplary embodiment, the control commands of the memory management circuit 502 may also be implemented in a form of hardware. For example, the memory management circuit 502 includes a microprocessor, a memory cell management circuit, a memory writing circuit, a memory reading circuit, a memory erasing circuit and a data processing circuit. The memory cell management circuit, the memory writing circuit, the memory reading circuit, the memory erasing circuit and the data processing circuit are coupled to the microprocessor. The memory cell management circuit is configured to manage the memory cells or a group thereof. The memory writing circuit is configured to issue a write command sequence for the rewritable non-volatile memory module 406 in order to write data into the rewritable non-volatile memory module 406. The memory reading circuit is configured to issue a read command sequence for the rewritable non-volatile memory module 406 in order to read data from the rewritable non-volatile memory module 406. The memory erasing circuit is configured to issue an erase command sequence for the rewritable non-volatile memory module 406 in order to erase data from the rewritable non-volatile memory module 406. The data processing circuit is configured to process both the data to be written into the rewritable non-volatile memory module 406 and the data to be read from the rewritable non-volatile memory module 406. Each of the write command sequence, the read command sequence and the erase command sequence may include one or more program codes or command codes, respectively, and instruct the rewritable non-volatile memory module 406 to perform the corresponding operations, such as writing, reading and erasing. In an exemplary embodiment, the memory management circuit 502 may further issue command sequences of other types to the rewritable non-volatile memory module 406 for instructing to perform the corresponding operations.

In the present exemplary embodiment, the memory management circuit 502 configures a plurality of logical units for mapping to the physical erasing units in the rewritable non-volatile memory module 406. Herein, one logical unit may refer to one logical address, one logical programming unit, one logical erasing unit, or may be constituted by a plurality of consecutive or non-consecutive logical addresses. In addition, one logical unit may be mapped to one or more physical erasing units.

In the present exemplary embodiment, the memory management circuit 502 records a mapping relationship (also known as a logical-to-physical mapping relationship) between the logical units and the physical erasing units into at least one logical-to-physical mapping table. When the host system 11 intends to read the data from the memory storage device 10 or write the data into the memory storage device 10, the memory management circuit 502 may access the data in the memory storage device 10 according to the logical-to-physical mapping table.

The host interface 504 is coupled to the memory management circuit 502 and configured to receive and identify commands and data sent from the host system 11. In other words, the commands and data sent from the host system 11 are passed to the memory management circuit 502 through the host interface 504. In the present exemplary embodiment, the host interface 504 is compatible with the SATA standard. However, it should be understood that the present disclosure is not limited thereto, and the host interface 504 may also be compatible with the PATA standard, the IEEE 1394 standard, the PCI Express standard, the USB standard, the SD standard, the UHS-I standard, the UHS-II standard, the MS standard, the MMC standard, the eMMC standard, the UFS standard, the CF standard, the IDE standard, or other suitable standards for data transmission.

The memory interface 506 is coupled to the memory management circuit 502 and configured to access the rewritable non-volatile memory module 406. That is, data to be written to the rewritable non-volatile memory module 406 is converted to a format acceptable to the rewritable non-volatile memory module 406 through the memory interface 506. Specifically, if the memory management circuit 502 intends to access the rewritable non-volatile memory module 406, the memory interface 506 sends corresponding command sequences. For example, the command sequences may include the write command sequence which instructs to write data, the read command sequence which instructs to read data, the erase command sequence which instructs to erase data, and command sequences configured to instruct performing various memory operations (e.g., for changing read voltage levels, performing a garbage collection process, and so on). These command sequences are generated by the memory management circuit 502 and transmitted to the rewritable non-volatile memory module 406 through the memory interface 506, for example. The command sequences may include one or more signals, or data on the bus. The signals or the data may include command codes and programming codes. For example, in a read command sequence, information such as identification codes and memory addresses are included.

The error checking and correcting circuit 508 is coupled to the memory management circuit 502 and configured to perform an error checking and correcting process to ensure correctness of the data. Specifically, when the memory management circuit 502 receives the write command from the host system 1, the error checking and correcting circuit 508 generates an ECC (error correcting code) and/or an EDC (error detecting code) for data corresponding to the write command, and the memory management circuit 502 writes data corresponding to the write command and the ECC and/or the EDC into the rewritable non-volatile memory module 406. Later, the memory management circuit 502 simultaneously reads the ECC and/or the EDC corresponding to the data when reading the data from the rewritable non-volatile memory module 406, and the error checking and correcting circuit 508 performs the error checking and correcting process on the read data based on the ECC and/or the EDC.

In an exemplary embodiment, the memory control circuit unit 404 further includes a buffer memory 510 and a power management circuit 512.

The buffer memory 510 is coupled to the memory management circuit 502 and configured to temporarily store data and commands from the host system 11 or data from the rewritable non-volatile memory module 406. The power management unit 512 is coupled to the memory management circuit 502 and configured to control a power of the memory storage device 10.

In the present exemplary embodiment, the error checking and correcting circuit 508 supports a low-density parity-check (LDPC) code. For example, the error checking and correcting circuit 508 may use the LDPC code for encoding and decoding. In the LDPC code, a valid codeword is defined by using a check matrix (also known as a parity check matrix). Hereinafter, the parity check matrix is marked as a matrix H and a codeword is marked as V. According to Equation (1) below, if a result of the parity check matrix H multiplied by the codeword V is a zero vector, it means that the codeword V is the valid codeword. Therein, an operator [symbol] represents a modulo-2 matrix multiplication. In other words, a null space of the matrix H includes all the valid codewords. However, the disclosure is not intended to limit the content of the codeword V. For example, the codeword V may also include the ECC or the EDC generated by using any algorithm.

H [symbol] V^{T}=0 (1)

Herein, a dimension of the matrix H is k-by-n, and a dimension of the codeword V is 1-by-n, where k and n are positive integers. The codeword V includes message bits and parity bits, that is, the codeword V may be represented by [U P], wherein a vector U is constituted by the message bits, and a vector P is constituted by the parity bits. A dimension of the vector U is 1-by-(n−k), and a dimension of the vector P is 1-by-k. In one codeword, the parity bits are used for protecting the message bits and may be considered as the ECC or the EDC generated in correspondence to the message bits. Herein, protecting the message bits refers to, for example, maintaining correctness of the message bits. For example, when data is read from the rewritable non-volatile memory module 406, the parity bits in said data may be used to correct possible errors in the corresponding data.

In an exemplary embodiment, the message bits and the parity bits in one codeword are collectively known as data bits. For example, the codeword V includes n data bits, wherein a length of the message bits is (n-k) bits, and a length of the parity bits is k bits. Accordingly, a code rate of the codeword V is (n-k)/n.

Generally, a generation matrix (hereinafter, marked as G) is used for encoding, such that Equation (2) below may be satisfied by the vector U being any vector. Herein, a dimension of the generation matrix G is (n-k)-by-n.

U [symbol] G=[UP]=V (2)

The codeword V generated by Equation (2) is the valid codeword. Therefore, when Equation (2) is substituted in Equation (1), Equation (3) below may be obtained accordingly.

H [symbol] G^{T} [symbol] U^{T}=0 (3)

Since the vector U may be any vector, Equation (4) below may definitely be satisfied. In other words, after the parity check matrix H is determined, the corresponding generation matrix G may also be determined.

H [symbol] G^{T}=0 (4)

When the codeword V is to be decoded, a parity check process is first performed on the data bits in the codeword V. For example, the parity check matrix H may be multiplied by the codeword V to generate one vector (hereinafter, marked as S, as shown in Equation (5) below). If the vector S is the zero vector (i.e., each element in the vector S is zero), it means that the decoding succeeds, and thus the codeword V may be outputted. If the vector S is not the zero vector (i.e., at least one element in the vector S is not zero), it means that the codeword V includes at least one error and the codeword V is not the valid codeword.

H [symbol] V^{T}=S (5)

A dimension of the vector S is k-by-1. Each element in the vector S is also known as a syndrome. If the codeword V is not the valid codeword, the error checking and correcting circuit 508 may perform a decoding process to attempt correcting errors in the codeword V.

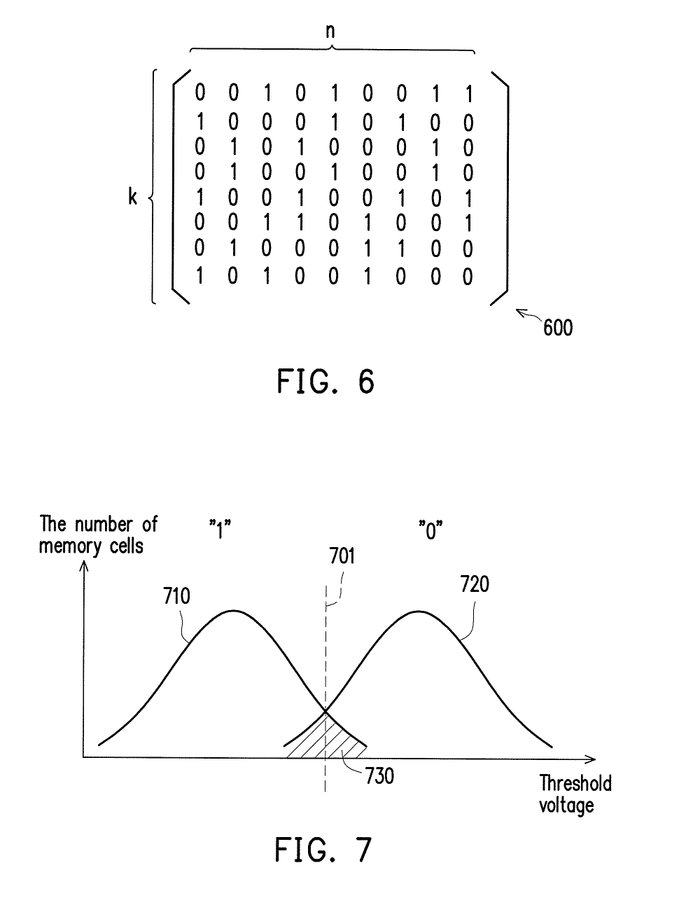

FIG. 6 is a schematic diagram illustrating a parity check matrix according to an exemplary embodiment of the disclosure.

Referring to FIG. 6, a parity check matrix 600 has a dimension being k-by-n. For example, k is 8 and n is 9. However, the disclosure is not intended to limit values of the positive integers k and n. Each row in the parity check matrix 600 also represents a constraint. Take a first row of the parity check matrix 600 for example, when one specific codeword is the valid codeword, the bit “0” may be obtained after performing a modulo-2 addition on third, fifth, eighth and ninth bits in the codeword. Person of ordinary skill in the art should be able to understand how to use the parity check matrix 600 for encoding, and thus related description is omitted hereinafter. In addition, the parity check matrix 600 is merely a sample matrix instead of limitation to the disclosure.

When the memory management circuit 502 intends to store a plurality of bits into the rewritable non-volatile memory module 406, the error checking and correcting circuit 508 generates corresponding k parity bits for each of (n−k) bit to be stored (i.e., the message bits). Next, the memory management circuit 502 writes the n bits (i.e., the data bits) as one codeword into the rewritable non-volatile memory module 406.

FIG. 7 is a schematic diagram illustrating threshold voltage distributions of the memory cells according to an exemplary embodiment of the disclosure.

Referring to FIG. 7, a horizontal axis represents the threshold voltage of the memory, and a vertical axis represents a number of the memory cells. For example, FIG. 7 illustrates the threshold voltage of each memory cell in one specific physical programming unit. It is assumed that a state 710 corresponds to the bit “1” (hereinafter, also known as a first bit value) and a state 720 corresponds to the bit “0” (hereinafter, also known as a second bit value). When the threshold voltage of one specific memory cell belongs to the state 710, the bit stored by the specific memory cell is the bit “I”; otherwise, if the threshold voltage of one specific memory cell belongs to the state 720, the bit stored by the specific memory cell is the bit “0”. It is noted that, in the present exemplary embodiment, one state of the threshold voltage distribution corresponds to one bit value, and the threshold voltage distribution of the memory cell includes two possible states. However, in other exemplary embodiments, each state in the threshold voltage distribution may also correspond to a plurality of bit values and the threshold voltage distribution of the memory cell may also include four, eight or any number of possible states. In addition, the bit represented by each state is not particularly limited by the disclosure. For example, in another exemplary embodiment of FIG. 7, it is also possible that the state 710 corresponds to the bit “0” while the state 720 corresponds to the bit “1”.

In the present exemplary embodiment, when it is intended to read the data from the rewritable non-volatile memory module 406, the memory management circuit 502 transmits a read command sequence to the rewritable non-volatile memory module 406. The read command sequence is configured to instruct the rewritable non-volatile memory module 406 to read a plurality of memory cells (hereinafter, also known as first memory cells) in one physical programming unit in order to obtain data stored in the first memory cells. For example, according to the read command sequence, the rewritable non-volatile memory module 406 may read the first memory cells by using a read voltage 701 in FIG. 7. If the threshold voltage of one of the first memory cells is lower than the read voltage 701, such memory cell is turned on so the memory management circuit 502 reads the bit “1”. Conversely, if the threshold voltage of one of the first memory cells is higher than the read voltage 701, such memory cell is not turned on so the memory management circuit 502 reads the bit “0”. Further, in another exemplary embodiment, one read operation may also refer to reading the memory cells in a plurality of the physical programming units or a part of memory cells in one physical programming unit, and the disclosure is not limited thereto.

In the present exemplary embodiment, an overlap region 730 is included between the state 710 and the state 720. An area of the overlap region 730 is positively correlated to a total number of the memory cells having the threshold voltage that falls within the overlap region 730 among the first memory cells. The overlap region 730 indicates that, some of the memory cells among the first memory cells should have each stored the bit “1” (which belongs to the state 710) and yet have the threshold voltage higher than the read voltage 701; or some of the memory cells among the first memory cells should have each stores the bit “0” (which belongs to the state 720) and yet have the threshold voltage lower than the read voltage 701. In other words, some of the bits include errors in the data read by applying the read voltage 701.

Generally, if usage time of the first memory cells is very short (e.g., a storage time of the data in the first memory cells is not long) and/or usage rate of the first memory cells is very low (e.g., a read count, a write count and/or an erase count of the first memory cells are not high), the area of the overlap region 730 is normally very small. In some cases, it is even possible that the overlap region 730 does not exist at all (i.e., the states 710 and 720 do not overlap with each other). Alternatively, when the memory storage device 10 just left the factory, the overlap region 730 normally does not exist. If the area of the overlap region 730 is very small or not existed, the data read from the first memory cells by applying the read voltage 701 usually includes fewer errors.

However, the area of the overlap region 730 will gradually increase with increases in usage time and/or usage rate of the rewritable non-volatile memory module 406 (or the first memory cells). For example, if usage time of the first memory cells is very long (e.g., the storage time of the data in the first memory cells is very long) and/or usage rate of the first memory cells is very high (e.g., the read count, the write count and/or the erase count of the first memory cells are very high), the area of the overlap region 730 will become larger (e.g., the states 710 and 720 becomes more flat and/or the states 710 and 720 are closer to each other). If the area of the overlap region 730 is very large, the data read from the first memory cells by applying the read voltage 701 usually include more errors. In other words, the area of the overlap region 730 is positively correlated to an occurrence rate of error bits (hereinafter, also known as an error bit occurrence rate) in the data read from the first memory cells.

In the present exemplary embodiment, after receiving the read data from the rewritable non-volatile memory module 406, the error checking and correcting circuit 508 performs a parity checking process to verify whether the data includes errors. If the data includes errors, the error checking and correcting circuit 508 may perform the decoding process to attempt correcting errors in the data.

In the present exemplary embodiment, the error checking and correcting circuit 508 performs an iteration decoding process. One iteration decoding process is configured to decode one data read from the rewritable non-volatile memory module 406. For example, one decoding unit in the data is one codeword. In one iteration decoding process, the parity checking process for checking correctness of the data and the decoding process for correcting errors in the data are performed repeatedly until the decoding succeeds or an iteration count reaches a predetermined count. If the iteration count reaches the predetermined count (which means that the decoding fails), the error checking and correcting circuit 508 stops decoding. In addition, if it is determined through the parity checking process that one specific data does not include errors, the error checking and correcting circuit 508 outputs the specific data.

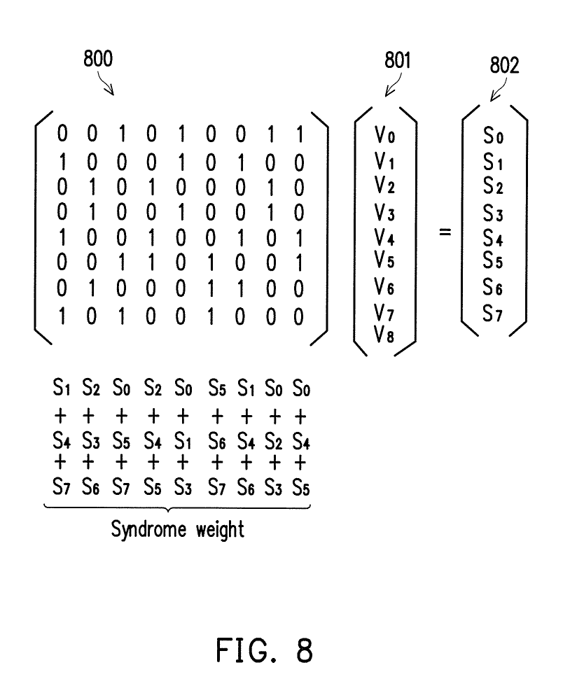

FIG. 8 is a schematic diagram illustrating a parity check process according to an exemplary embodiment of the disclosure.

Referring to FIG. 8, it is assumed that the data read from the first memory cells includes a codeword 801. In the parity checking process, a parity check matrix 800 is multiplied by the codeword 801 to obtain a syndrome vector 802 (i.e., the vector S) according to Equation (5). Herein, each bit in the codeword 801 corresponds to at least one element (i.e., the syndrome) in the syndrome vector 802. For instance, a bit V₀ in the codeword 801 (corresponding to a first column of the parity check matrix 800) corresponds to syndromes S₁, S₄ and S₇; a bit V₁ (corresponding to a second column of the parity check matrix 800) corresponds to syndromes S₂, S₃ and S₆; and the rest may be deduced by analogy. If the bit V₀ is the error bit, at least one of the syndromes S₁, S₄ and S₇ may be “1”. If the bit V₁ is the error bit, at least one of the syndromes S₂, S₃ and S₆ may be “1”, and the rest may be deduced by analogy.

In other words, if the syndromes S₀ to S₇ are all “0”, it means that codeword 801 may not include any error bit, and thus the error checking and correcting circuit 508 may directly output the codeword 801. However, if the codeword 801 includes at least one error bit, at least one of the syndromes S₀ to S₇ may be “1”, and thus the error checking and correcting circuit 508 performs one decoding process on the codeword 801.

In the present exemplary embodiment, the error checking and correcting circuit 508 supports one or more decoding algorithms. For example, the error checking and correcting circuit 508 may support at least one of the decoding algorithms including a Bit-Flipping algorithm, a Min-Sum algorithm, a Sum-Product algorithm, but the types of usable decoding algorithm are not limited by the above. After determining that the data includes errors, the error checking and correcting circuit 508 performs one decoding process based on one decoding algorithm. In addition, two consecutively performed decoding processes may be performed based on identical decoding algorithm or different decoding algorithms.

In the present exemplary embodiment, the memory management circuit 502 estimates the error bit occurrence rate of the data before performing a decoding process on one specific data. Herein, if the estimated error bit occurrence rate is higher, it means that a probability for the specific data to include the error bit may be higher and/or a total number of error bits in the specific data may be more. According to the estimated error bit occurrence rate, the error checking and correcting circuit 508 uses one decoding parameter to perform the decoding process on the data. Herein, the decoding parameter is configured to adjust a strict level, for locating the error bit in the decoding process, used by the error checking and correcting circuit 508.

In the present exemplary embodiment, the strict level relates to a criterion for determining the error bit. For example, if a higher strict level is used for locating the error bit, the criterion for determining the error bit in the data used by the error checking and correcting circuit 508 is more strict, and thus a misjudge rate for determining any bit in the data as the error bit may be reduced. However, a number of corrected error bits in one decoding process may be reduced correspondingly, such that the error checking and correcting circuit 508 may have to perform more decoding processes in order to correct all errors in the data. In other words, if the higher strict level is used for locating the error bit, although a number of required decoding processes may be increased, the misjudge rate for determining certain bits in the data as the error bit may be reduced. In certain cases (e.g., when the estimated error bit occurrence rate of the data is higher), the decoding efficiency of the data may be improved by using the higher strict level for locating the error bit in the decoding process.

On the other hand, if a lower strict level is used for locating the error bit, the criterion for determining the error bit in the data used by the error checking and correcting circuit 508 is looser, such that the number of bits being identified as the error bits and then corrected may become more. However, the misjudge rate of the bits may be correspondingly increased, such that the error checking and correcting circuit 508 may repeatedly change the bit value of the same bit in the data in a plurality of consecutively performed decoding processes. In other words, if the lower strict level is used for locating the error bit, although certain bits in the data may be repeatedly corrected in the different decoding processes, more error bits may be corrected in the same decoding process. In certain cases (e.g., when the estimated error bit occurrence rate of the data is lower), the decoding efficiency of the data may be improved by using the lower strict level for locating the error bit in the decoding process.

Generally, if the data to be decoded includes more error bits (e.g., when the total number of error bits exceeds a preset value), it is to be taken into consideration that each decoding process has a limited decoding success rate, and whether each bit in the data is correctly corrected in one decoding process is highly related to whether the entire data is successfully decoded, the number of times the decoding process is performed on the data and/or a time required to complete decoding. Accordingly, in the present exemplary embodiment, if the estimated error bit occurrence rate of the data is higher, the error checking and correcting circuit 508 uses the decoding parameter corresponding to the higher strict level to perform the decoding process on the data.

On the other hand, if the data to be decoded includes fewer error bits (e.g., when the total number of error bits is less than the preset value), each decoding process has a higher decoding success rate, and any one decoding process is able to correct all or most of the error bits in the data. Accordingly, in the present exemplary embodiment, if the estimated error bit occurrence rate of the data is lower, the error checking and correcting circuit 508 uses the decoding parameter corresponding to the lower strict level to perform the decoding process on the data. In other words, the strict level for locating the error bit in the decoding process performed on one specific data is positively correlated to the estimated error bit occurrence rate of the specific data. By doing so, regardless of whether the data to be decoded includes more or less error bits, a higher probability for speeding up a convergence of error bits and improving the decoding efficiency may be provided.

In the present exemplary embodiment, the error checking and correcting circuit 508 is preset to perform the iteration decoding process according to the Bit-flipping algorithm. In such iteration decoding process, each decoding process attempts to correct (hereinafter, also known as flip) at least one bit in the data. For example, the error checking and correcting circuit 508 identifies the bit that needs to be flipped (i.e., the error bit) in the data based on a flipping threshold. That is to say, in the present exemplary embodiment, the decoding parameter used by the error checking and correcting circuit 508 refers to the flipping threshold corresponding to the Bit-flipping algorithm.

Referring to FIG. 8, in one decoding process, the error checking and correcting circuit 508 calculates a syndrome weight of each bit in the codeword 801 according to the parity check matrix 800 and the syndrome vector 802. For example, the error checking and correcting circuit 502 adds the syndromes corresponding to the same bit in the codeword 801 together in order to obtain the syndrome weight of the respective bit. As shown in FIG. 8, the syndrome weight of the bit V₀ is equal to a sum of the syndromes S₁, S₄ and S₇; the syndrome weight of the bit V₁ is equal to a sum of the syndromes S₂, S₃ and S₆; and the rest may be deduced by analogy. It should be noted that, the addition applied on the syndromes S₀ to S₇ is a normal addition in stead of the modulo-2 addition. For example, the error checking and correcting circuit 208 may obtain the syndrome weight of each bit in the codeword 801 by using Equation (6) below. Herein, each element in a vector f may be used to represent the syndrome weight of each bit in the codeword.

f=S^{T}×H (6)

After selecting one decoding parameter (i.e., the flipping threshold), the error checking and correcting circuit 508 may correct all or at least one part of the bits in the codeword 801 having the syndrome weight greater than the decoding parameter. For example, if the decoding parameter is “1” and the syndrome weights of the bits V₁, V₃ and V₅ in the codeword 801 are all greater than “1”, the error checking and correcting circuit 508 synchronously flips the three bits V₁, V₃ and V₅ in the current decoding process. Herein, flipping one specific bit refers to flipping the bit value of the specific bit from “1” to “0”, or from “0” to “1”. Alternatively, if the decoding parameter is “2” and only the syndrome weights of the bits V₃ and V₅ in the codeword 801 are greater than “2”, the error checking and correcting circuit 508 flips the two bits V₃ and V₅ in the current decoding process. For example, values of the bits V₃ and V₅ are flipped from “1” to “0”, or flipped from “0” to “1”, respectively.

In the present exemplary embodiment, the decoding parameter (e.g., the flipping threshold) used by one specific decoding process is positively correlated to the strict level for locating the error bit in this decoding process. From another perspective, the decoding parameter (e.g., the flipping threshold) used by one specific decoding process is positively correlated to the estimated error bit occurrence rate. If the estimated error bit occurrence rate is higher, the larger decoding parameter is accordingly used in the subsequently performed decoding process. For example, in an exemplary embodiment of FIG. 8, if the estimated error bit occurrence rate is higher (e.g., higher than a preset criterion), the error checking and correcting circuit 508 temporarily uses “2” as the flipping threshold. Conversely, if the estimated error bit occurrence rate is lower, the smaller decoding parameter is accordingly used in the subsequently performed decoding process. For example, in an exemplary embodiment of FIG. 8, if the estimated error bit occurrence rate is lower (e.g., lower than a preset criterion), the error checking and correcting circuit 508 temporarily uses “1” as the flipping threshold. By doing so, in an exemplary embodiment, if the estimated error bit occurrence rate is higher, a total number of the bits flipped in the same decoding process may be fewer; if the estimated error bit occurrence rate is lower, the total number of the bits flipped in the same decoding process may be more. Nonetheless, the total number of the bits actually flipped in each decoding process may increase or decrease according to the channel status of the first memory cells, and the disclosure is not limited thereto.

In an exemplary embodiment, if the channel status of the first memory cells (or the physical programming unit or the physical erasing unit containing the first memory cells) is better, the estimated error bit occurrence rate of the data read from the first memory cells is lower. Conversely, if the channel status of the first memory cells (or the physical programming unit or the physical erasing unit containing the first memory cells) is worse, the estimated error bit occurrence rate of the data read from the first memory cells is higher.

In an exemplary embodiment, the memory management circuit 502 obtains the threshold voltage distribution of the first memory cells and accordingly estimates the error bit occurrence rate of the data read from the first memory cells. Take FIG. 7 for example, the memory management circuit 502 may estimate the error bit occurrence rate of the data read from the first memory cells according to a total number of the memory cells corresponding to the overlap region 730 between the states 710 and 720. Herein, the area size of the overlap region 730 is positively correlated to the total number of the memory cells having the threshold voltage included in the overlap region 730. For example, the memory management circuit 502 may search a look-up table according to the area size of the overlap region 730 and/or the total number of the memory cells having the threshold voltage included in the overlap region 730 in order to obtain the corresponding error bit occurrence rate of the data. Alternatively, the memory management circuit 502 may also input the area size of the overlap region 730 and/or the total number of the memory cells having the threshold voltage included in the overlap region 730 into an algorithm and use an output of such algorithm as the error bit occurrence rate of the data.

In an exemplary embodiment, if one specific physical programming unit and another physical programming unit belong to the same physical erasing unit, it is highly possible that the data read from said two physical programming units having the identical or similar error bit occurrence rate. Therefore, in an exemplary embodiment, assuming that the physical programming unit to which the first memory cells belong is belonging to one specific physical erasing unit in the rewritable non-volatile memory module 406, the memory management circuit 502 may store the total number of error bits, which is obtained through a successful decoding, in the data read from another physical programming unit also belonging to the physical erasing unit. According to said total number, the memory management circuit 502 may estimate a total number of possible error bits in the data read from the first memory cells and/or the corresponding error bit occurrence rate.

In an exemplary embodiment, the memory management circuit 502 may also estimate the error bit occurrence rate of the data read from the first memory cells by using any information related to a wear degree of the first memory cells (e.g., the storage time of the data in the first memory cells, the read count, the write count and/or the erase count of the first memory cells, etc.). For example, in correspondence to the different values of the read count, the write count and/or the erase count, the memory management circuit 502 may obtain the corresponding error bit occurrence rate by searching a look-up table or using a specific algorithm.

In the present exemplary embodiment, the memory management circuit 502 estimates the error bit occurrence rate of the data to be decoded by directly using an execution result of the parity checking process. For example, in an exemplary embodiment of FIG. 8, the memory management circuit 502 accumulates the syndromes S₀ to S₇ in the syndrome vector 802 to obtain a syndrome sum. Herein, the accumulation refers to the normal addition in stead of the modulo 2 addition. The syndrome sum may be used to represent how many “1” (or how many “0”) are included in the syndromes S₀ to S₇. For example, if three “1” are included in the syndromes S₀ to S₇, the syndrome sum is “3”. For example, if seven “1” are included in the syndromes S₀ to S₇, the syndrome sum is “7”. Generally, if the codeword 801 includes more error bits, the more “1” will be included in the syndromes S₀ to S₇, so the syndrome sum is larger. If the codeword 801 includes fewer error bits, the fewer “1” will be included in the syndromes S₀ to S₇, so the syndrome sum is smaller. Therefore, the estimated error bit occurrence rate is positively correlated to the syndrome sum.

It is noted that, the disclosure is not intended to limit the format for representing the estimated error bit occurrence rate. For example, the error bit occurrence rate of specific data may be represented by the followings (or may use the followings as the basis of estimation): at least one of the probability for at least one bit in the data being the error bit, the overall bit error rate of the data, the total number of error bits in the data, the wear degree of the first memory cells (the read count, the write count and/or the erase count of the first memory cells, etc.) and the syndrome sum, or other values related to the error bit occurrence rate.

In the present exemplary embodiment, the memory management circuit 502 searches a look-up table according to the values related to the error bit occurrence rate of the data such as the syndrome sum, so as to obtain a decoding parameter to be used in the subsequent decoding process. Alternatively, the memory management circuit 502 may also input the values related to the error bit occurrence rate of the data such as the syndrome sum into an algorithm and use the output of such algorithm as the decoding parameter to be used in the subsequent decoding process. For example, in order to output the corresponding decoding parameter, such algorithm may include: determining whether the values related to the error bit occurrence rate (such as the syndrome sum) are greater than or less than a threshold, determining one of value ranges to which the values related to the error bit occurrence rate (such as the syndrome sum) fall within, or substituting the values related to the error bit occurrence rate (such as the syndrome sum) into a specific equation.

In an exemplary embodiment, the operation of obtaining the decoding parameter according to the values related to the error bit occurrence rate (such as the syndrome sun) may be performed by a hardware circuit included by the error checking and correcting circuit 508, so as to accelerate an overall decoding speed.

In an exemplary embodiment, if a plurality of consecutively performed decoding processes are included in the same iteration decoding process, the error bit occurrence rate of the data to be decoded may change during the decoding processes, and the decoding parameters used in at least part of the decoding processes may also be adaptively changed. As such, as errors in the data are gradually corrected, the strict level for locating the error bit used in the decoding process may be appropriately adjusted even without changing the decoding algorithm, and as a result, the decoding efficiency can be improved. For example, at the beginning that the decoding process is performed on specific data, the error bit occurrence rate corresponding to the data is higher (e.g., the data includes more errors), the error checking and correcting circuit 508 first performs the decoding process by using the higher strict level, so as to avoid error divergence in the data caused by too many misjudgments in one decoding process. However, as errors in the data are gradually corrected, the total number of error bits in the data gradually decreases, so that the error bit occurrence rate of the data is also reduced. Accordingly, in the subsequent decoding processes, the error checking and correcting circuit 508 may use the lower strict level instead, so that the overall decoding speed may be improved without significantly reducing the decoding success rate of each of the decoding processes.

For example, it is assumed that, after estimating the error bit occurrence rate of the data read from the first memory cells, the error checking and correcting circuit 508 performs one specific decoding process (hereinafter, also known as a first decoding process) on the data by using one specific decoding parameter (hereinafter, also known as a first decoding parameter). Herein, the first decoding parameter corresponds to a strict level for locating an error bit in the first decoding process. Later, the memory management circuit 502 (or the error checking and correcting circuit 508) determines whether the first decoding process fails. If the first decoding process fails (i.e., the data still includes errors), the memory management circuit 502 (or the error checking and correcting circuit 508) re-estimates the error bit occurrence rate of the data according to an execution result of the first decoding process. According to the re-estimated error bit occurrence rate, the error checking and correcting circuit 508 performs another decoding process (hereinafter, also known as a second decoding process) on the data to be decoded by using another decoding parameter (hereinafter, also known as a second decoding parameter). Herein, the second decoding parameter corresponds to the strict level for locating the error bit in the second decoding process. In addition, according to the re-estimated error bit occurrence rate, the second decoding parameter may be different from or identical to the first decoding parameter. Particularly, if the second decoding parameter is different from the first decoding parameter, the strict levels for locating the error bit used in the first decoding process and the second decoding process are different as well.

In an exemplary embodiment, the error checking and correcting circuit 508 may also change the decoding algorithm being used. For example, if it is still unable to correct all errors in the data after performing the decoding processes on specific data for a preset number of times based on the Bit-flipping algorithm, the error checking and correcting circuit 508 may switch using the Min-Sum algorithm, the Sum-Product algorithm and the like, so as to continually perform more decoding processes on the data. Alternatively, the error checking and correcting circuit 508 may also be preset to perform the decoding process by using the algorithms such as the Min-Sum algorithm, the Sum-Product algorithm and the like, and the disclosure is not limited thereto. In addition, although the flipping threshold corresponding to the bit-flipping algorithm is used as an example of the decoding parameter in the foregoing exemplary embodiments, if the error checking and correcting circuit 508 performs the decoding process by using the other algorithms such as the Min-Sum algorithm, the Sum-Product algorithm and the like in another exemplary embodiment, it is also possible that the error checking and correcting circuit 508 may use decoding parameters of other types to adjust the strict level for locating the error bit in the corresponding decoding process. In other words, regardless of which decoding algorithm is used to perform the decoding process, as long as one specific parameter may be used to adjust or control the strict level for locating the error bit in one specific decoding process, that specific parameter may be regarded as aforesaid decoding parameter and may be selectively used according to the estimated error bit occurrence rate.

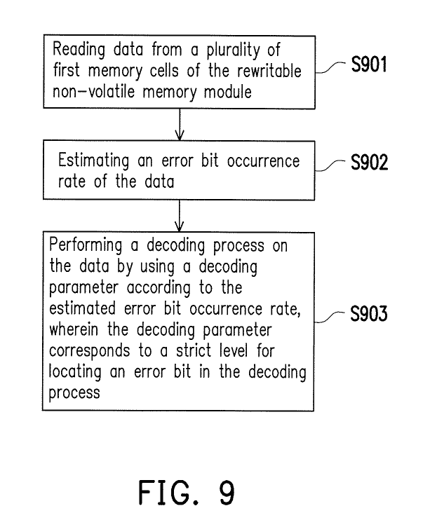

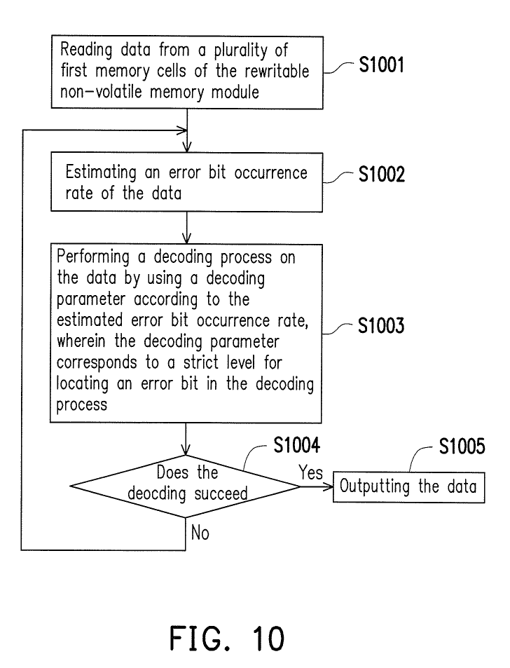

FIG. 9 is a flowchart illustrating a decoding method according to an exemplary embodiment of the disclosure.

Referring to FIG. 9, in step S901, data is read from a plurality of first memory cells of the rewritable non-volatile memory module. In step S902, an error bit occurrence rate of the data (i.e., the data to be decoded) is estimated. In step S903, a decoding process is performed on the data (i.e., the data to be decoded) by using a decoding parameter according to the estimated error bit occurrence rate, wherein the decoding parameter corresponds to a strict level for locating the error bit in the decoding process.

FIG. 10 is a flowchart illustrating a decoding method according to another exemplary embodiment of the disclosure.

Referring to FIG. 10, in step S1001, data is read from a plurality of first memory cells of the rewritable non-volatile memory module. In step S1002, an error bit occurrence rate of the data (i.e., the data to be decoded) is estimated. In step S1003, a decoding process is performed on the data (i.e., the data to be decoded) by using a decoding parameter according to the estimated error bit occurrence rate, wherein the decoding parameter corresponds to a strict level for locating the error bit in the decoding process. In step S1004, whether the decoding succeeds is determined. If yes, in step S1005, the successfully decoded data is outputted. If no (i.e., the decoding fails), the method returns to step S1002, in which the error bit occurrence rate of the data to be decoded is re-estimated according to an execution result of the previous decoding process. Then, in step S1003, a next decoding process is performed on the data (i.e., the data to be decoded) by using another decoding parameter according to the re-estimated error bit occurrence rate, wherein the another decoding parameter corresponds to the strict level for locating the error bit in the next decoding process.

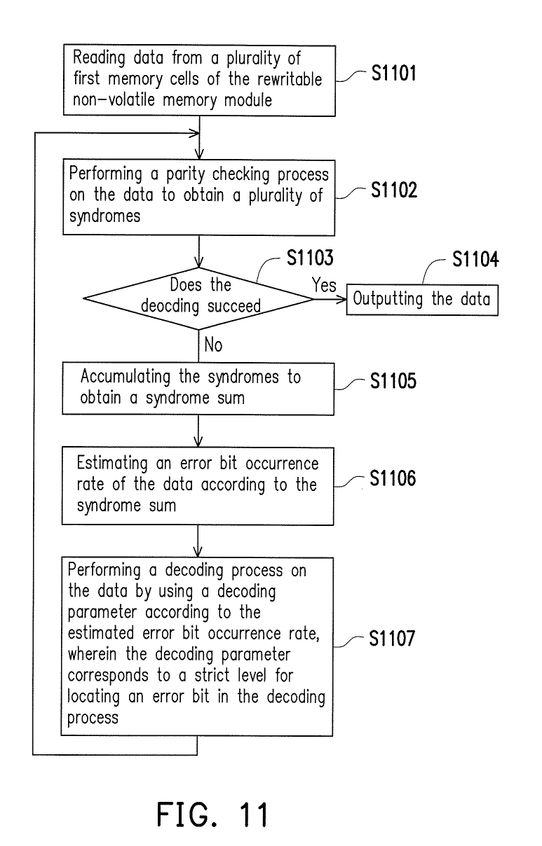

FIG. 11 is a flowchart illustrating a decoding method according to another exemplary embodiment of the disclosure.

Referring to FIG. 11, in step S1101, data is read from a plurality of first memory cells of the rewritable non-volatile memory module. In step S1102, a parity checking process is performed on the data (i.e., the data to be decoded) to obtain a plurality of syndromes. In step S1103, whether the decoding succeeds is determined according to the obtained syndromes. If the decoding succeeds, in step S1104, the successfully decoded data is outputted. If no (i.e., the decoding does not succeed), in step S1105, the syndromes are accumulated to obtain a syndrome sum. In step S1106, an error bit occurrence rate of the data (i.e., the data to be decoded) is estimated according to the syndrome sum. In step S1107, a first decoding process is performed on the data (i.e., the data to be decoded) by using a first decoding parameter according to the estimated error bit occurrence rate, wherein the first decoding parameter corresponds to a strict level for locating the error bit in the first decoding process. After the first decoding process is completed, the method returns to step S1102, the parity checking process is performed again on the data (i.e., the data to be decoded) to obtain the syndromes. In step S1103, whether the decoding succeeds is determined according to the re-obtained syndromes. If yes, the successfully decoded data is outputted. If no (i.e., the decoding fails), in step S1105, the syndromes are accumulated again to obtain the syndrome sum. In step S1106, the error bit occurrence rate of the data (i.e., the data to be decoded) is estimated again according to the re-calculated syndrome sum. In step S1107, a second decoding process is performed on the data (i.e., the data to be decoded) by using a second decoding parameter according to the estimated error bit occurrence rate, wherein the second decoding parameter corresponds to the strict level for locating the error bit in the second decoding process. In an exemplary embodiment, steps S1102, S1103 and S1105 to S1107 are performed repeatedly until the decoding succeeds (i.e., entering step S104) or a total number of times the decoding processes is performed (i.e., the iteration count) reaches a predetermined count. For example, if the iteration count reaches the predetermined count, the decoding process is stopped.

Nevertheless, each of steps depicted in FIG. 9 to FIG. 11 have been described in detail as above, and thus related description thereof is not repeated hereinafter. It should be noted that, the steps depicted in FIG. 9 to FIG. 11 may be implemented as a plurality of program codes or circuits, which are not particularly limited in the disclosure. Moreover, the methods disclosed in FIG. 9 to FIG. 11 may be implemented with reference to above embodiments, or may be implemented separately, which are not particularly limited in the disclosure.

In summary, according to the error bit occurrence rate of the data to be decoded, the error checking and correcting circuit may flexibly perform the corresponding decoding process based on one specific decoding parameter. The decoding parameter corresponds to the strict level for locating the error bit in the corresponding decoding process. As a result, a balance between improving the decoding success rate of each decoding process and improving the overall decoding speed may be accomplished, and the decoding efficiency of the memory storage device may be improved.

The previously described exemplary embodiments of the present disclosure have the advantages aforementioned, wherein the advantages aforementioned not required in all versions of the disclosure. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A decoding method for a rewritable non-volatile memory module comprising a plurality of memory cells, the decoding method comprising:
reading data from a plurality of first memory cells among the memory cells;
estimating an error bit occurrence rate of the data before performing a first decoding process on the data; and
performing the first decoding process on the data by using a first decoding parameter according to the estimated error bit occurrence rate,
wherein the first decoding parameter corresponds to a strict level for locating an error bit in the first decoding process.

2. The decoding method of claim 1, wherein the step of estimating the error bit occurrence rate of the data comprises:
obtaining a threshold voltage distribution of the first memory cells, wherein the threshold voltage distribution comprises a first state and a second state, wherein the first state corresponds to a first bit value, wherein the second state corresponds to a second bit value, wherein the first bit value is different from the second bit value; and
estimating the error bit occurrence rate of the data according to a total number of memory cells corresponding to an overlap region between the first state and the second state.

3. The decoding method of claim 1, wherein the step of estimating the error bit occurrence rate of the data comprises:
performing a parity checking process on the data to obtain a plurality of syndromes;
accumulating the syndromes to obtain a syndrome sum;
estimating the error bit occurrence rate of the data according to the syndrome sum,
wherein the estimated error bit occurrence rate is positively correlated to the syndrome sum.

4. The decoding method of claim 1, wherein the strict level is positively correlated to the estimated error bit occurrence rate.

5. The decoding method of claim 1, wherein the strict level is positively correlated to the first decoding parameter.

6. The decoding method of claim 5, wherein the first decoding parameter is positively correlated to the estimated error bit occurrence rate.

7. The decoding method of claim 6, wherein the first decoding parameter is a flipping threshold, wherein the first decoding process comprises:
obtaining a syndrome weight corresponding to each bit in the data; and
flipping at least one bit having the syndrome weight greater than the flipping threshold in the data.

8. The decoding method of claim 1, further comprising:
re-estimating the error bit occurrence rate of the data according to an execution result of the first decoding process if the first decoding process fails; and
performing a second decoding process on the data by using a second decoding parameter according to the re-estimated error bit occurrence rate,
wherein the second decoding parameter corresponds to a strict level for locating an error bit in the second decoding process.

9. A memory storage device, comprising:
a connection interface unit, configured to couple to a host system;
a rewritable non-volatile memory module, wherein the rewritable non-volatile memory module comprises a plurality of memory cells; and
a memory control circuit unit, coupled to the connection interface unit and the rewritable non-volatile memory module,
wherein the memory control circuit unit is configured to send a read command sequence which instructs reading data from a plurality of first memory cells among the memory cells,
wherein the memory control circuit unit is further configured to estimate an error bit occurrence rate of the data before performing a first decoding process on the data,
wherein the memory control circuit unit is further configured to perform the first decoding process on the data by using a first decoding parameter according to the estimated error bit occurrence rate,
wherein the first decoding parameter corresponds to a strict level for locating an error bit in the first decoding process.

10. The memory storage device of claim 9, wherein the operation of estimating the error bit occurrence rate of the data by the memory control circuit unit comprises:
obtaining a threshold voltage distribution of the first memory cells, wherein the threshold voltage distribution comprises a first state and a second state, wherein the first state corresponds to a first bit value, wherein the second state corresponds to a second bit value, wherein the first bit value is different from the second bit value; and
estimating the error bit occurrence rate of the data according to a total number of memory cells corresponding to an overlap region between the first state and the second state.

11. The memory storage device of claim 9, wherein the operation of estimating the error bit occurrence rate of the data by the memory control circuit unit comprises:
performing a parity checking process on the data to obtain a plurality of syndromes;
accumulating the syndromes to obtain a syndrome sum; and
estimating the error bit occurrence rate of the data according to the syndrome sum,
wherein the estimated error bit occurrence rate is positively correlated to the syndrome sum.

12. The memory storage device of claim 9, wherein the strict level is positively correlated to the estimated error bit occurrence rate.

13. The memory storage device of claim 9, wherein the strict level is positively correlated to the first decoding parameter.

14. The memory storage device of claim 13, wherein the first decoding parameter is positively correlated to the estimated error bit occurrence rate.

15. The memory storage device of claim 14, wherein the first decoding parameter is a flipping threshold, wherein the first decoding process comprises:
obtaining a syndrome weight corresponding to each bit in the data; and
flipping at least one bit having the syndrome weight greater than the flipping threshold in the data.

16. The memory storage device of claim 9, wherein the memory control circuit unit is further configured to re-estimate the error bit occurrence rate of the data according to an execution result of the first decoding process if the first decoding process fails,
wherein the memory control circuit unit is further configured to perform a second decoding process on the data by using a second decoding parameter according to the re-estimated error bit occurrence rate,
wherein the second decoding parameter corresponds to a strict level for locating an error bit in the second decoding process.

17. A memory control circuit unit, for controlling a rewritable non-volatile memory module, wherein the rewritable non-volatile memory module comprises a plurality of memory cells, and the memory control circuit unit comprises:
a host interface, configured to couple to a host system;
a memory interface, configured to couple to the rewritable non-volatile memory module;
an error checking and correcting circuit; and
a memory management circuit, coupled to the host interface, the memory interface and the error checking and correcting circuit,
wherein the memory management circuit is configured to send a read command sequence which instructs reading data from a plurality of first memory cells among the memory cells,
wherein the memory management circuit is further configured to estimate an error bit occurrence rate of the data before performing a first decoding process on the data,
wherein the error checking and correcting circuit is configured to perform the first decoding process on the data by using a first decoding parameter according to the estimated error bit occurrence rate,
wherein the first decoding parameter corresponds to a strict level for locating an error bit in the first decoding process.

18. The memory control circuit unit of claim 17, wherein the operation of estimating the error bit occurrence rate of the data by the memory management circuit comprises:
obtaining a threshold voltage distribution of the first memory cells, wherein the threshold voltage distribution comprises a first state and a second state, wherein the first state corresponds to a first bit value, wherein the second state corresponds to a second bit value, wherein the first bit value is different from the second bit value; and
estimating the error bit occurrence rate of the data according to a total number of memory cells corresponding to an overlap region between the first state and the second state.

19. The memory control circuit unit of claim 17, wherein the operation of estimating the error bit occurrence rate of the data by the memory management circuit comprises:
performing a parity checking process on the data to obtain a plurality of syndromes;
accumulating the syndromes to obtain a syndrome sum; and
estimating the error bit occurrence rate of the data according to the syndrome sum,
wherein the estimated error bit occurrence rate is positively correlated to the syndrome sum.

20. The memory control circuit unit of claim 17, wherein the strict level is positively correlated to the estimated error bit occurrence rate.

21. The memory control circuit unit of claim 17, wherein the strict level is positively correlated to the first decoding parameter.

22. The memory control circuit unit of claim 21, wherein the first decoding parameter is positively correlated to the estimated error bit occurrence rate.

23. The memory control circuit unit of claim 22, wherein the first decoding parameter is a flipping threshold, wherein the first decoding process comprises:
obtaining a syndrome weight corresponding to each bit in the data; and
flipping at least one bit having the syndrome weight greater than the flipping threshold in the data.

24. The memory control circuit unit of claim 17, wherein the memory management circuit is further configured to re-estimate the error bit occurrence rate of the data according to an execution result of the first decoding process if the first decoding process fails,
wherein the error checking and correcting circuit is further configured to perform a second decoding process on the data by using a second decoding parameter according to the re-estimated error bit occurrence rate,
wherein the second decoding parameter corresponds to a strict level for locating an error bit in the second decoding process.
